(19) United States
(12) Patent Application Publication
(10) Pub. No.: US 2006/0189104 A1
(43) Pub. Date: Aug. 24, 2006

(54) METHOD FOR FORMING A QUANTUM DOT PATTERN

(75) Inventor: SHUO-TING YAN, TUCHENG (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/307,725

(22) Filed: Feb. 18, 2006

(30) Foreign Application Priority Data
Feb. 24, 2005 (CN) 200510033325.0

(51) Int. Cl. H01L 21/20

(52) U.S. Cl. 438/478; 438/962; 438/507; 438/708

(57) ABSTRACT

A method of forming at least one quantum dot is disclosed. A substrate having a single crystal structure is provided. An insulating layer is formed on the substrate. At least one opening is defined in the insulating layer, thereby exposing at least one corresponding portion of the substrate. At least one quantum dot having a crystal structure is grown, each quantum dot being epitaxially grown on a corresponding exposed portion of the substrate. The insulating layer is removed, thereby obtaining the at least one quantum dot on the substrate.

### FIELD OF THE INVENTION

The present invention relates to a method for forming a quantum dot pattern.

### DESCRIPTION OF RELATED ART

A quantum dot is an essentially zero-dimensional quantum structure having a size of about 100 Angstroms. According to the quantum mechanics theory, a quantum dot structure has better optical properties than a quantum well structure. When a growth thickness of the quantum dot structure reaches up to about 100 Angstroms, quantization effects associated therewith occur and the original electron energy is quantized to discrete energy levels along a growth direction of the quantum dot structure. With rapid developments in epitaxy techniques, high quality quantum well semiconductor materials have been successfully implemented into quantum devices such as quantum well lasers, high electron mobility transistors, quantum well infrared detectors, and so on.

However, it is difficult to put quantum well structures into practical applications due to the surface states formed in the quantum well structures during manufacture. For example, U.S. Pat. No. 5,229,320 (the content of which is hereby incorporated by reference) discloses a method for forming quantum dots, in which quantum dots are defined in a quantum well structure by photolithography and etching techniques. However, a plurality of the undesired surface states are created during manufacture of such dots. These surface states may give rise to the formation of non-radiative recombination centers in the quantum dots, thereby degrading the optical properties of the quantum dots.

What is needed, therefore, is to provide an improved method for forming a quantum dot pattern, which can avoid the formation of surface states.

### SUMMARY OF INVENTION

In view of shortcomings as described above, in one embodiment in accordance with this invention provides a method for forming a quantum dot pattern. Such a method includes the following steps: providing a substrate having a single crystal structure; forming an insulating layer on the substrate; defining at least one opening in the insulating layer, thereby exposing at least one corresponding portion of the substrate; growing at least one quantum dot having a crystal structure, each quantum dot being epitaxially grown on a corresponding exposed portion of the substrate; and removing the insulating layer, thereby obtaining the at least one quantum dot on the substrate. Therefore, after growing a given quantum dot in a particular opening, there is no need to perform additional steps to define any or all of the quantum dots. Thus, the occurrence of surface states during manufacture is effectively avoided, whereby the superior optical property of the quantum dots is ensured.

Other advantages and novel features will become more apparent from the following detailed description of embodiments when taken in conjunction with the accompanying drawings.

### BRIEF DESCRIPTION OF DRAWINGS

Many aspects of the invention can be better understood with reference to the following drawings. The components in the drawings are not necessarily to scale, the emphasis instead being placed upon clearly illustrating the principles of the present method of quantum dot formation. Moreover, in the drawings, like reference numerals designate corresponding parts throughout the several views.

FIG. 1 is a schematic, cross-sectional view of illustrating a single-crystal substrate having an insulating layer formed thereon, in accordance with a preferred embodiment;

FIGS. 2-4 are schematic, cross-sectional views illustrating the process for forming substrate-exposing openings in the insulating layer and for re-exposing the remaining insulating layer material, in accordance with a preferred embodiment;

FIG. 5 is a schematic, cross-sectional view of illustrating quantum dots formed in the openings of the insulating layer, in accordance with a preferred embodiment; and

FIG. 6 is similar to FIG. 5, but showing that the remaining insulating layer has been removed to complete the quantum dot formation, in accordance with a preferred embodiment.

The exemplifications set out herein illustrate at least one preferred embodiment of the invention, in one form, and such exemplifications are not to be construed as limiting the scope of the invention in any manner.

### DETAILED DESCRIPTION

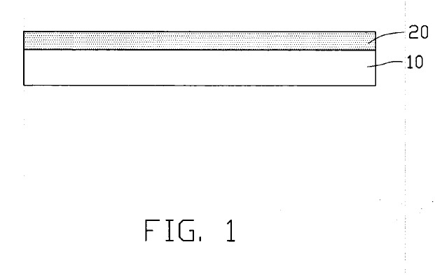

FIGS. 1-6 together illustrate successive stages in a process for forming a quantum dot pattern, in accordance with a preferred embodiment.

Referring to FIG. 1, a substrate 10 having a single-crystal structure is provided. The substrate 10 is advantageously made of a semiconductor material, for example, aluminum nitride (AlN), germanium, or silicon. Alternatively, the material for the substrate 10 could be made of a compound semiconductor other than AlN, such as any of the III-VI compound semiconductors and II-VI compound semiconductors. The compound semiconductors may be binary, ternary, or quaternary.

An insulating layer 20 is a ceramic material formed on the substrate 10 by a deposition process. Such a material may potentially be amorphous, polycrystalline, or a single crystal. The insulating layer generally has a thickness of about 100 nm. The insulating layer 20 advantageously may be made of a material selected from, but not to be limited to, the group consisting of silicon dioxide (SiO2) or, more generically, a silicon oxide (SiOx), silicon nitride (Si3N4), silicon carbide (SiC), silicon oxycarbide (SiOC), and silicon carbon nitride (SiCN). In the illustrated embodiment, the substrate 10 is made of aluminum nitride; and the insulating layer 20 is made of a silicon oxide.

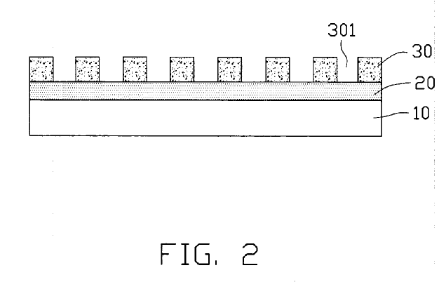

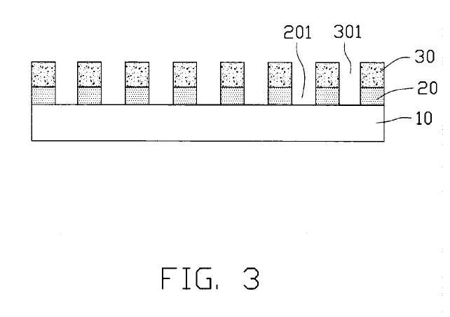

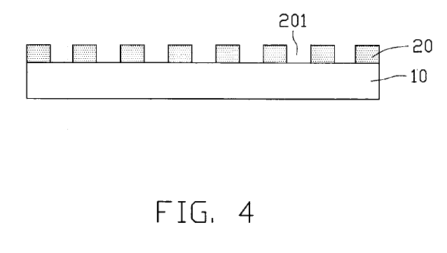

As shown in FIGS. 2-4, a plurality of openings 201 is defined in the insulating layer 20 for exposing a plurality of predetermined portions of the substrate 10. Referring to FIG. 2, a mask layer 30 is formed on the insulating layer 20. The mask layer 30 has a pattern 301. The pattern 301 may be formed in the mask layer 301 by, e.g., photolithography, hot embossing lithography, or step and flash imprint lithography. Referring to FIG. 3, a plurality of openings 201 is thereby defined in the insulating layer 20. The configuration of the openings 201 corresponds with the pattern 301. The openings 201 each have a chosen diameter in the range from 1 nm to about 100 nm. In the illustrated embodiment, the diameter of each opening 201 is configured to be no more than about 20 nm. The openings 201 may be defined, for example, by a wet etching process, a plasma etching process, or a reactive ion etching process. Referring to FIG. 4, the mask layer 30 is removed by an etching process such as a wet etching process.

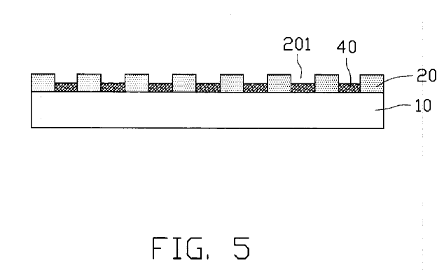

Referring to FIG. 5, a plurality of quantum dots 40 is grown in the openings 201 by a selective epitaxy growth technique (i.e., epitaxially grown). The quantum dots 40 may be formed by, e.g., a metal organic chemical vapor deposition process, an ultra high vacuum chemical vapor deposition process, or a molecular beam epitaxy process and so forth. As stated above, the substrate 10 and the insulating layer 20 have different structures. The substrate 10 has a single crystal structure, while the insulating layer 30 has a ceramic structure. According to the selective epitaxy growth mechanism, the quantum dots 40 are grown on uncovered portions of the substrate 10, while they are not grown or, at least, are not readily grown on the insulating layer 20. Therefore, the quantum dots 40 are discretely and regularly formed on the substrate 10. The quantum dots 40 each have a crystal structure that is identical with or similar to that of the substrate 10. The quantum dots 40 may, e.g., be III-VI compound semiconductors, II-VI compound semiconductors, silicon, or germanium. In the illustrated embodiment, the quantum dots 40 are made of gallium nitride (GaN).

The principle of the selective epitaxy growth mechanism is explained as follows. Generally, a quantum dot grown on a substrate has a crystal structure that is similar to the crystal structure of the substrate. Additionally, the crystal structure of the quantum dot is different from the ceramic structure of the insulating layer 20. Therefore, the quantum dots 40 may be grown on uncovered portions of the substrate 10 while they cannot be grown or are not readily grown on the insulating layer 20. In other words, the quantum dots 40 can be selectively grown on the uncovered portion of the substrate 10 while not so on the insulating layer 20. There are two types of selective epitaxy growth mechanisms that may advantageously be employed, in accordance with this present embodiment. One is that a quantum dot 40 can only be grown on the substrate 10 other than the insulating layer 20. The other one is that a quantum dot 40 is not readily grown on the insulating layer 20, or to be more accurate, an incubation time of a quantum dot growing on the substrate 10 is considerably shorter than that of the quantum dot growing on the insulating layer 20. The incubation time is a time period from the beginning of an epitaxial growth process until a quantum dot begins to grow (at least noticeably/discernably). In this case, we can control the growth time of a quantum dot growing on the substrate 10 to be shorter than the incubation time of the quantum dot growing on the insulating layer 20, thereby achieving the selective formation of the quantum dots on the substrate 10.

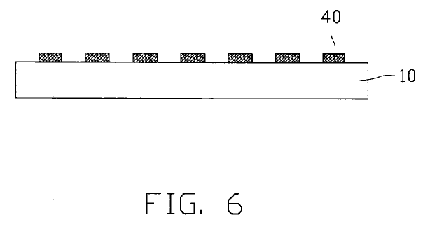

Referring to FIG. 6, the insulating layer 20 is removed, thereby leaving the quantum dots 40, completed and ready for operation, on the substrate 10. The insulating layer 20 may be removed using an etching process such as a wet etching process, a plasma etching process, or a reactive ion etching process. In the illustrated embodiment, the quantum dots 40 have a grain size of no more than 20 nm.

As stated above, after growing quantum dots 40 in the openings 201, there is no need to perform additional steps to define the quantum dots. Thus, the occurrence of surface states during manufacture thereof is effectively avoided, whereby the superior optical property of the quantum dots is ensured.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A method of forming at least one quantum dot, comprising the steps of:
providing a substrate having a single crystal structure;
forming an insulating layer on the substrate;
defining at least one opening in the insulating layer, thereby exposing at least one corresponding portion of the substrate;
growing at least one quantum dot having a crystal structure, each quantum dot being epitaxially grown on a corresponding exposed portion of the substrate; and
removing the insulating layer, thereby obtaining the at least one quantum dot on the substrate.

2. The method of claim 1, wherein the substrate is a semiconductor.

3. The method of claim 2, wherein the substrate is comprised of a material selected from the group consisting of silicon, germanium, III-V compound semiconductors, and II-VI compound semiconductors.

4. The method of claim 1, wherein the insulating layer is comprised of a material selected from the group consisting of silicon oxide, silicon nitride, silicon carbide, silicon oxycarbide, and silicon carbon nitride.

5. The method of claim 1, wherein the quantum dot is comprised of a material selected from the group consisting of III-V compound semiconductors, II-VI compound semiconductors, silicon, and germanium.

6. The method of claim 1, wherein a given opening is defined in the insulating layer by the steps of:
forming a mask layer on the insulating layer, the mask layer having a pattern; and
defining the given opening in the insulating layer by a photolithography process, the given opening corresponding to the pattern of the mask layer.

7. The method of claim 1, wherein the step of growing each quantum dot is performed by a process selected from the group consisting of a metal organic chemical vapor deposition process, an ultra high vacuum chemical vapor deposition process, and a molecular beam epitaxy process.

8. The method of claim 1, wherein the insulating layer is removed by a process selected from the group consisting of a wet etching process, a plasma etching process, and a reactive ion etching process.

9. The method of claim 1, wherein the grain size of each quantum dot is about in the range from 1 nm to 20 nm.
